(19) United States
(12) Patent Application Publication
(10) Pub. No.: US 2025/0343218 A1
(43) Pub. Date: Nov. 6, 2025

(54) SEMICONDUCTOR PACKAGE

(71) Applicant: Samsung Electronics Co., Ltd., Suwon-si (KR)

(72) Inventors: Jungmin KO, Suwon-si (KR); Hyunhee LEE, Suwon-si (KR)

(21) Appl. No.: 18/942,723

(22) Filed: Nov. 10, 2024

(30) Foreign Application Priority Data
May 3, 2024 (KR) 10-2024-0059191

(51) Int. Cl. H01L 25/18; H01L 23/00; H10B 80/00

(52) U.S. Cl. CPC H01L 25/18; H01L 24/14; H01L 24/16; H01L 24/32; H01L 24/73; H01L 2224/14131; H01L 2224/16148; H01L 2224/16227; H01L 2224/32145; H01L 2224/32225; H01L 2224/73204; H01L 2225/06513; H01L 2225/06517; H01L 2225/06541; H01L 2924/3511; H10B 80/00

(57) ABSTRACT

Provided is a semiconductor package that includes a package substrate, a first semiconductor chip comprising a first region and a second region arranged to surround the first region, a plurality of first layer bumps arranged in a first layout, wherein the first semiconductor chip comprises a first wiring structure disposed on the plurality of first layer bumps, the plurality of first layer bumps comprise a first bump group and a second bump group arranged alternately in a first direction, the first bump group includes a first dummy bump unit comprising a plurality of bumps overlapping the second region, the second bump group includes a second dummy bump unit comprising a plurality of bumps overlapping the second region, the bumps of the first dummy bump unit are unconnected to the first wiring structure, and the bumps of the second dummy bump unit are connected to the first wiring structure.

### CROSS-REFERENCE TO RELATED APPLICATION(S)

This application claims the benefit of priority under 35 U.S.C. § 119 to Korean Patent Application No. 10-2024-0059191, filed on May 3, 2024, in the Korean Intellectual Property Office, the disclosure of which is incorporated herein by reference.

### BACKGROUND

### 1. Field of the Invention

Example embodiments relate to a semiconductor package.

### 2. Description of the Related Art

Due to the development of the electronics industry, demands for higher functionality, higher speed, and smaller electronic components are increasing. In response to this trend, research and development is continuously being conducted on semiconductor chips containing a through silicon via (TSV) structure and semiconductor packages containing the semiconductor chips.

Required are improvements on short circuit between adjacent bumps due to the miniaturization of semiconductor packages and improvements in heat dissipation in the semiconductor chip stack structure.

### SUMMARY

An aspect provides a semiconductor package with reduced risk of short circuit between adjacent bumps.

Another aspect also provides a semiconductor package with improved heat dissipation characteristics.

The technical tasks to be achieved by the present example embodiments are not limited to the technical tasks described above, and other technical tasks may be inferred from the following example embodiments by those skilled in the art.

According to an aspect, there is provided a semiconductor package including a package substrate, a first semiconductor chip including a first region disposed on the package substrate and a second region disposed on the package substrate and arranged to surround the first region, and a plurality of first layer bumps arranged in a first layout on a bottom part of the first semiconductor chip, wherein the first semiconductor chip includes a first wiring structure disposed on the plurality of first layer bumps, the plurality of first layer bumps include a first bump group and a second bump group arranged alternately in a first direction, the first bump group includes a first bump line group formed by a plurality of first bump lines arranged in the first direction, the plurality of first bump lines overlapping the first region and including a plurality of first bumps arranged in rows along a second direction intersecting the first direction and a first dummy bump unit including a plurality of first dummy bumps overlapping the second region, the second bump group includes a second bump line group formed by a plurality of second bump lines arranged in the first direction, the plurality of second bump lines overlapping the first region and including a plurality of second bumps arranged in rows along the second direction and a second dummy bump unit including a plurality of second dummy bumps overlapping the second region, the plurality of first dummy bumps of the first dummy bump unit are not connected to the first wiring structure, and the plurality of second bumps of the second dummy bump unit are connected to the first wiring structure.

According to another aspect, there is provided a semiconductor package including a package substrate, a first semiconductor chip disposed on the package substrate and including a first region and a second region surrounding the first region, and a plurality of first layer bumps disposed on a bottom part of the first semiconductor chip in a first layout, wherein the first semiconductor chip includes a first wiring structure disposed on the plurality of first layer bumps, the plurality of first layer bumps disposed in the first layout include a first bump group and a second bump group that are arranged alternately in a first direction, the first bump group includes a first bump line group formed by a plurality of first bump lines arranged in the first direction, the plurality of first bump lines overlapping the first region and including a plurality of first bumps arranged in rows along a second direction intersecting the first direction, the second bump group includes a second bump line group formed by a plurality of second bump lines arranged in the first direction, the plurality of second bump lines overlapping the first region and including a plurality of second bumps arranged in rows along the second direction, the first bump line group includes a first adjacent bump line adjacent to the second bump group disposed on one side of the first bump group in the first direction, a second adjacent bump line disposed on another side of the first bump group in the first direction, the second bump line group includes a third adjacent bump line that is disposed on one side of the second bump group in the first direction and is adjacent to the first adjacent bump line and a fourth adjacent bump line that is disposed on another side of the second bump group in the first direction, and bumps of the first adjacent bump line and bumps of the fourth adjacent bump line are not connected to the first wiring structure and the first wiring structure.

According to another aspect, there is provided a semiconductor package including a package substrate, a first semiconductor chip that includes a first region disposed on the package substrate, a second region disposed on the package substrate and arranged to surround the first region, and a third region disposed on the package substrate and disposed across the first region and the second region, and a plurality of first layer bumps disposed on a bottom part of the first semiconductor chip, wherein the first semiconductor chip includes a first wiring structure disposed on the plurality of first layer bumps, first front surface connection pads disposed between the first wiring structure and the plurality of first layer bumps, a first semiconductor substrate disposed on the first wiring structure, and a first through via that penetrates the first semiconductor substrate and is connected to the first wiring structure, wherein the plurality of first layer bumps include a first bump group and a second bump group that are arranged alternately in a first direction, the first bump group includes a first bump line group formed by a plurality of first bump lines arranged in the first direction, the plurality of first bump lines overlapping the first region and including a plurality of first bumps arranged in rows along a second direction intersecting the first direction, a first dummy bump unit including a plurality of first dummy bumps overlapping the second region, the second bump group includes a second bump line group formed by a plurality of second bump lines arranged in the first direction, the plurality of second bump lines overlapping the first region and including a plurality of second bumps arranged in rows along the second direction, and a second dummy bump unit including a plurality of second dummy bumps overlapping the second region, the first bump line group includes a first adjacent bump line that is disposed on one side of the first bump group in the first direction and is adjacent to the second bump group, and a second adjacent bump line disposed on another side of the first bump group in the first direction, the first wiring structure includes a first top wiring disposed closest to the first front surface connection pads in a third direction intersecting the first direction and the second direction, the first adjacent bump line includes bumps that are not connected with the first top wiring, the second adjacent bump line includes bumps that are connected with the first top wiring, the first dummy bump unit includes bumps that are not connected with the first top wiring, the second dummy bump unit includes bumps that are connected with the first top wiring, and the first through via overlaps the third region but does not overlap the first region and the second region in the third direction.

According to another aspect, there is provided a semiconductor package including a package substrate, a first semiconductor chip disposed on the package substrate and including a first region and a second region surrounding the first region, and a plurality of first layer bumps disposed on a bottom part of the first semiconductor chip, wherein the first semiconductor chip includes a first wiring structure disposed on the plurality of first layer bumps, first front surface connection pads disposed between the first wiring structure and the plurality of first layer bumps, a first semiconductor substrate disposed on the first wiring structure, and a first through via that penetrates the first semiconductor substrate and is connected to the first wiring structure, wherein the plurality of first layer bumps include a first bump group and a second bump group arranged alternately in a first direction, the first bump group includes a first bump line group formed by a plurality of first bump lines arranged in the first direction, the plurality of first bump lines overlapping the first region and including a plurality of first bumps arranged in rows along a second direction intersecting the first direction, a first dummy bump unit including a plurality of first dummy bumps overlapping the second region, the second bump group includes a second bump line group formed by a plurality of second bump lines arranged in the first direction, the plurality of second bump lines overlapping the first region and including a plurality of second bumps arranged in rows along the second direction, and a second dummy bump unit including a plurality of second dummy bumps overlapping the second region, the first wiring structure includes a first top wiring disposed closest to the first front surface connection pads in a third direction intersecting the first direction and the second direction, connection pads of the first front surface connection pads disposed on the plurality of first dummy bumps of the first dummy bump unit are spaced apart from the first top wiring in the third direction, and connection pads of the first front surface connection pads disposed on the plurality of second dummy bumps of the second dummy bump unit are in contact with the first top wiring.

Additional aspects of example embodiments will be set forth in part in the description which follows and, in part, will be apparent from the description, or may be learned by practice of the disclosure.

According to example embodiments, it is possible to reduce the risk of short circuits between adjacent bumps of the semiconductor package.

According to example embodiments, it is possible to improve the heat dissipation characteristics of the semiconductor package.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a layout diagram for explaining a semiconductor chip in a semiconductor package according to an example embodiment;

FIG. 2 is a diagram illustrating the layout of bumps of a semiconductor package according to an example embodiment;

FIG. 3 is a cross-sectional view taken along line A-A of FIG. 2;

FIG. 4 is an enlarged view illustrating a part P1 of FIG. 3;

FIG. 5 is a cross-sectional view taken along line B-B of FIG. 2;

FIG. 6 is an enlarged view illustrating a part P2 of FIG. 5;

FIG. 7 is a cross-sectional view taken along line C-C of FIG. 2;

FIG. 8 is an enlarged view illustrating a part P3 of FIG. 7;

FIG. 9 is a cross-sectional view taken along line D-D of FIG. 2;

FIG. 10 is an enlarged view illustrating a part P4 of FIG. 9;

FIG. 11 is a cross-sectional view taken along line E-E of FIG. 2;

FIG. 12 is an enlarged view illustrating a part P5 of FIG. 11;

FIG. 13 is a cross-sectional view to explain a semiconductor package according to an example embodiment;

FIG. 14 is a layout diagram of a semiconductor package according to an example embodiment; and

FIGS. 15 to 21 are intermediate process diagrams for explaining a method of manufacturing a semiconductor package according to an example embodiment.

### DETAILED DESCRIPTION

Prior to the detailed description of the present disclosure, terms or words used in the specification and claims should not be construed according to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only example embodiments of the present disclosure, and do not necessarily represent the entire technical idea of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Hereinafter, example embodiments according to the technical idea of the present disclosure will be described with reference to the attached drawings. Like reference characters refer to like elements throughout.

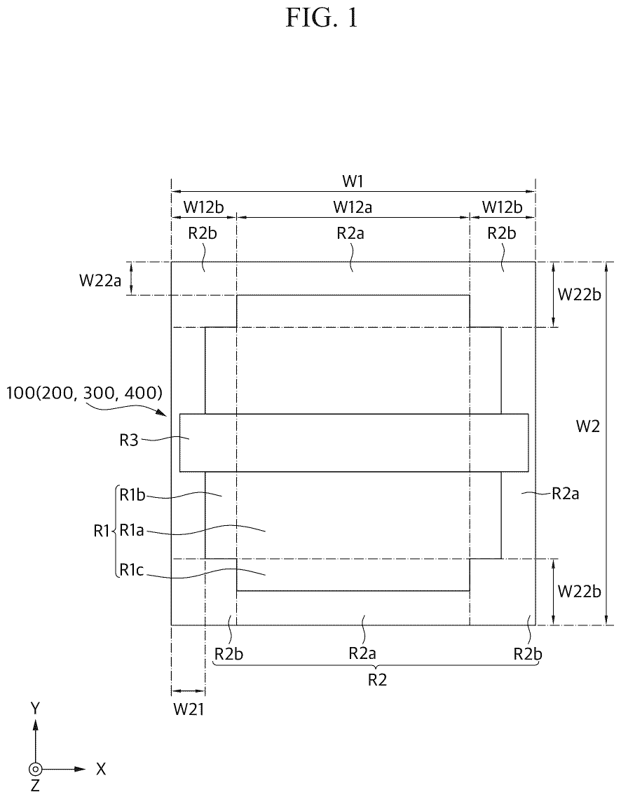

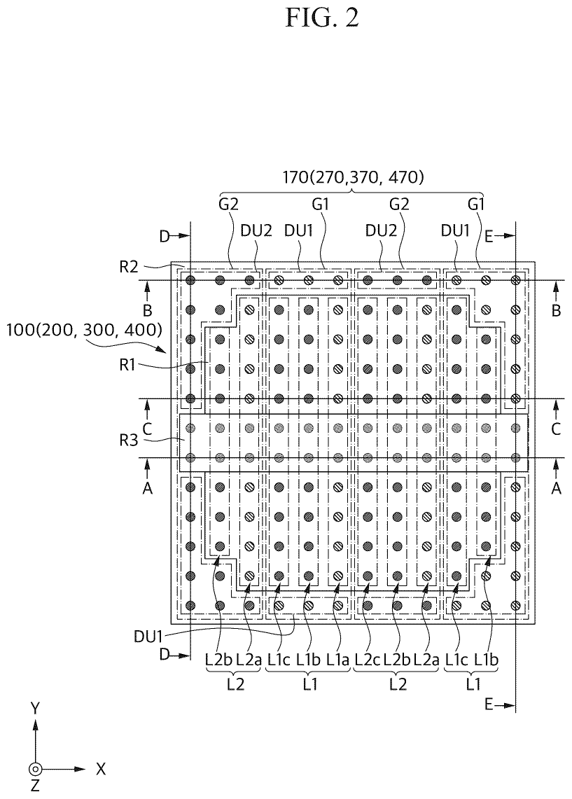

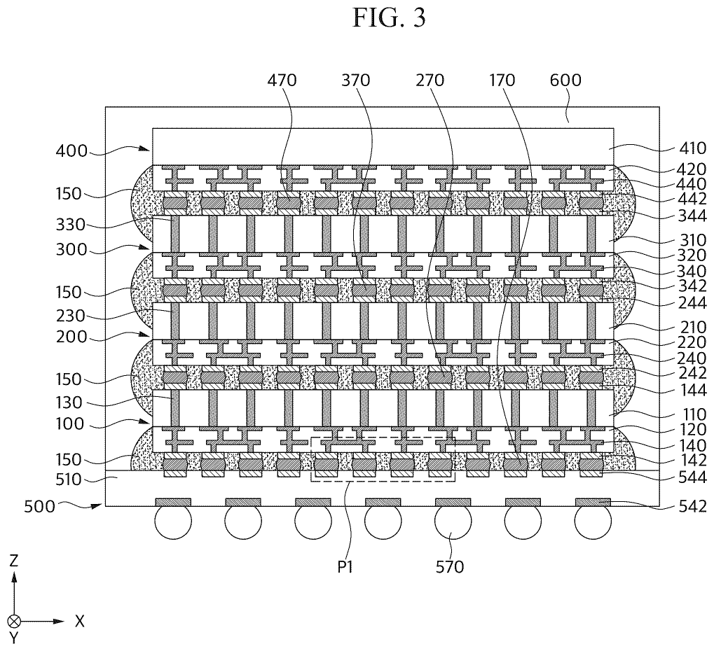

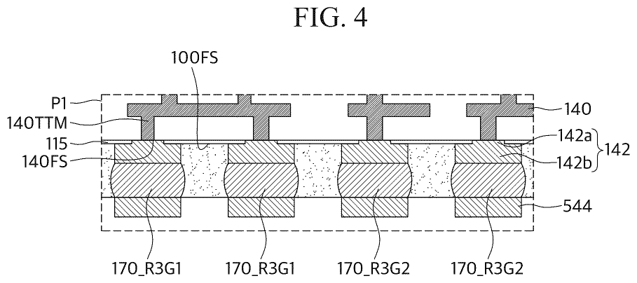

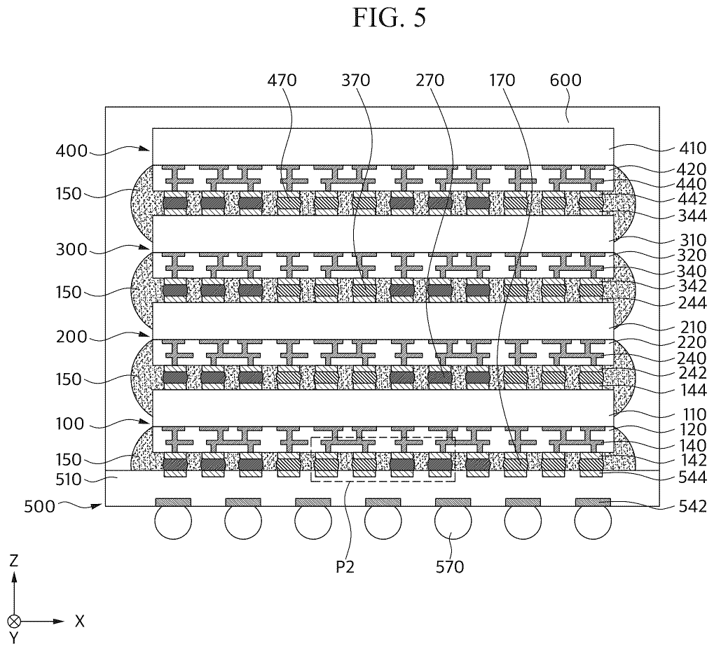

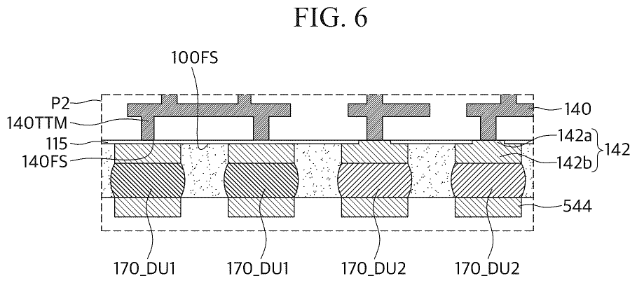

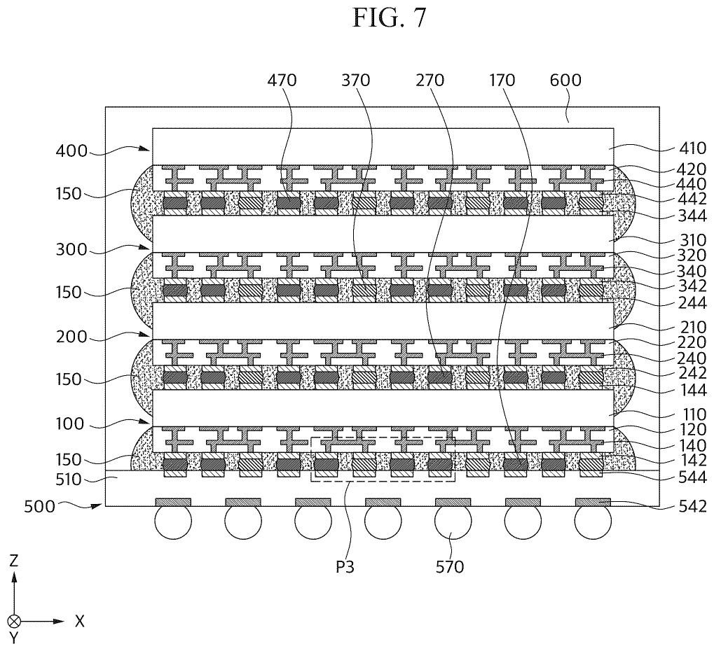

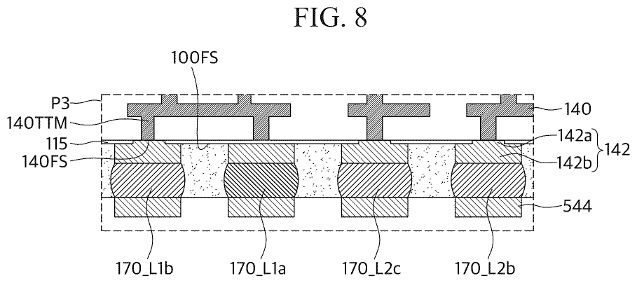

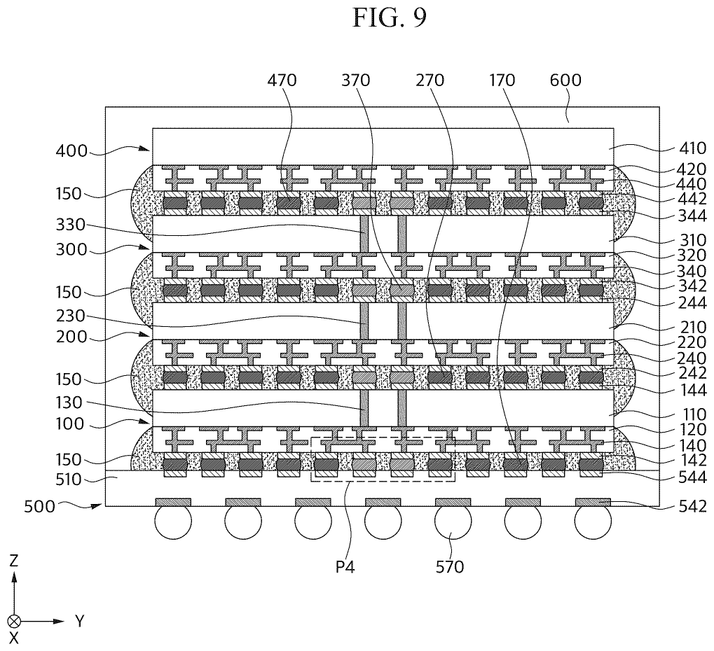

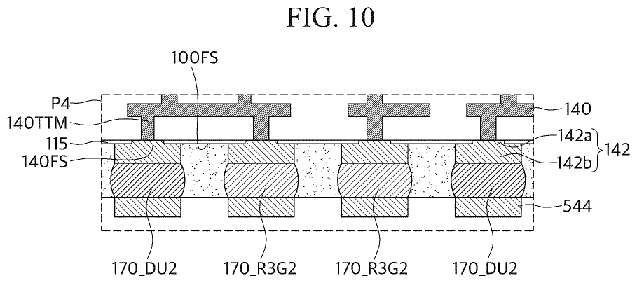

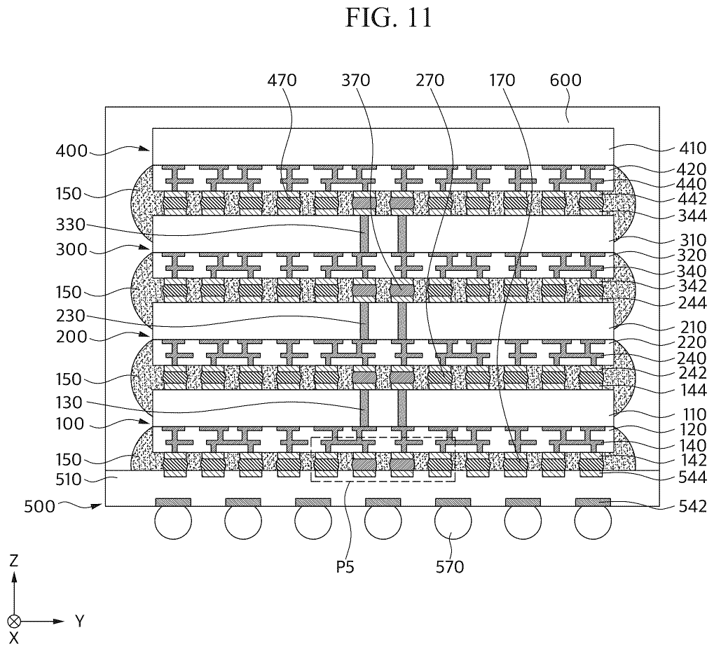

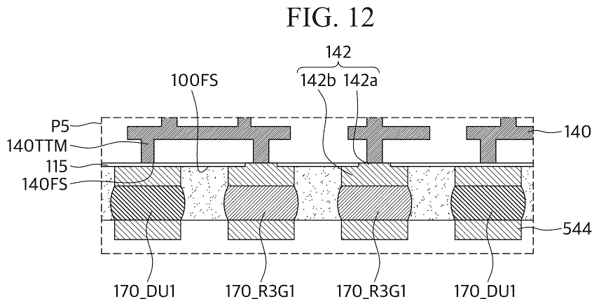

FIG. 1 is a layout diagram for explaining a semiconductor chip in a semiconductor package according to an example embodiment. FIG. 2 is a diagram illustrating the layout of bumps of a semiconductor package according to an example embodiment. FIG. 3 is a cross-sectional view taken along line A-A of FIG. 2. FIG. 4 is an enlarged view illustrating the part P1 of FIG. 3. FIG. 5 is a cross-sectional view taken along line B-B of FIG. 2. FIG. 6 is an enlarged view illustrating the part P2 of FIG. 5. FIG. 7 is a cross-sectional view taken along line C-C of FIG. 2. FIG. 8 is an enlarged view illustrating the part P3 of FIG. 7. FIG. 9 is a cross-sectional view taken along line D-D of FIG. 2. FIG. 10 is an enlarged view illustrating the part P4 of FIG. 9. FIG. 11 is a cross-sectional view taken along line E-E of FIG. 2. FIG. 12 is an enlarged view illustrating the part P5 of FIG. 11.

Referring to FIGS. 1 to 3, a first semiconductor chip 100, a second semiconductor chip 200, a third semiconductor chip 300, and a fourth semiconductor chip 400 of a semiconductor package may include a first region R1, a second region R2, and a third region R3.

According to some example embodiments, the first region R1 may be placed in the center of the first semiconductor chip 100, the second semiconductor chip 200, the third semiconductor chip 300 and the fourth semiconductor chip 400. The first region R1 may be surrounded by the second region R2. For example, the first region R1 may have a cross shape.

According to some example embodiments, the first region R1 may include a center part R1a, a first protruding part R1b, and a second protruding part R1c. The center part R1a may be surrounded by the first protruding part R1b and the second protruding part R1c. The first protruding part R1b may be formed by protruding outward from the center part R1a in the first direction X. In example embodiments, the first protruding part R1b may be formed on both sides of the center part R1a in the first direction X such that one first protruding part R1b may protrude from one side of the center part R1a (e.g., a positive first direction X) and another first protruding part R1b may protrude from the opposite side of the center part R1a (e.g., a negative first direction X). The second protruding part R1c may be formed by protruding outward from the center part R1a in the second direction Y. In example embodiments, the second protruding part R1c may be formed on both sides of the center part R1a in the second direction Y such that one second protruding part R1c may protrude from one side of the center part R1a (e.g., a positive second direction Y) and another second protruding part R1c may protrude from the opposite side of the center part R1a (e.g., a negative second direction Y).

According to some example embodiments, the distance W21 between the outer circumference of the second region R2 and first protruding part R1b in the first direction X may be smaller than the distance between the outer circumference of the second region R2 and the first protruding part R1b in the second direction Y. The distance between the outer circumference of the second region R2 and the first protruding part R1b in the second direction Y is equal to the width W22b of the edge part in the second direction Y.

According to some example embodiments, the second region R2 may be arranged along the edges of the first semiconductor chip 100, the second semiconductor chip 200, the third semiconductor chip 300, and the fourth semiconductor chip 400. The second region R2 may surround the first region R1. The second region R2 may have the shape of any area other than the cross shape of the first region R1 among the square shapes of the first semiconductor chip 100, the second semiconductor chip 200, the third semiconductor chip 300, and the fourth semiconductor chip 400.

According to some example embodiments, the second region R2 may include an extension part R2a and an edge part R2b. For example, in the first direction X or the second direction Y, the extension part R2a has a rectangular shape with a long side and a short side, and may be formed by extending in a direction parallel to the long side. Here, the extension direction of the extension part R2a may be the first direction X or the second direction Y. The extension part R2a may be placed in the central area between edge parts R2b in an extension direction parallel to the long side.

According to some example embodiments, the edge part R2b may be placed on both sides of the extension part R2a. For example, the edge part R2b may be placed on both sides of the extension part R2a extending in the first direction X and the extension part R2a extending in the second direction Y. The edge part R2b may be placed at the edge of the first semiconductor chip 100, the second semiconductor chip 200, the third semiconductor chip 300, and the fourth semiconductor chip 400.

According to some example embodiments, in the direction in which the extension part R2a extends, the width of the extension part R2a may be greater than the width of the edge part R2b. For example, the width W12a of the extension part R2a with respect to the first direction X extending in the first direction X may be greater than the width W12b with respect to the first direction X of the edge part R2b.

According to some example embodiments, in the direction intersecting the direction in which the extension part R2a extends, the width of the extension part R2a may be smaller than the width of the edge part R2b. For example, the width W22a with respect to the second direction Y of the extension part R2a extending in the first direction X may be smaller than the width W22b with respect to the second direction Y of the edge part R2b. In the direction intersecting the direction in which the extension part R2a extends, the width of the extension part R2a, for example, the length of the short side of the extension part R2a, may be 8% or less of the length of one side of the outer circumference of the first semiconductor chip 100, the second semiconductor chip 200, the third semiconductor chip 300, and the fourth semiconductor chip 400. For example, the width W21 with respect to the first direction X of the extension part R2a extending in the second direction Y may be equal to 8% or less than 8% of the outer circumference length W1 extending in the first direction X of the first semiconductor chip 100, the second semiconductor chip 200, the third semiconductor chip 300, and the fourth semiconductor chip 400.

According to some example embodiments, the width of the edge part R2b may be equal to 15% or less than 15% of the length of one side of the outer circumference of the first semiconductor chip 100, the second semiconductor chip 200, the third semiconductor chip 300, and the fourth semiconductor chip 400. For example, the width W12b of the edge part with respect to the first direction X may be equal to 15% or less than 15% of the outer circumference length W1 extending in the first direction X of the first semiconductor chip 100, the second semiconductor chip 200, the third semiconductor chip 300 and the fourth semiconductor chip 400. The width W22b of the edge part with respect to the second direction Y may be equal to 15% or less than 15% of the outer circumference length W2 extending in the second direction Y of the first semiconductor chip 100, the second semiconductor chip 200, the third semiconductor chip 300, and the fourth semiconductor chip 400.

According to some example embodiments, the edge part R2b may be a weak point prone to warpage due to heat generated within the semiconductor package. Heat dissipation may be facilitated through a structure in which the bumps of either a first dummy bump unit DU1 or a second dummy bump unit DU2 disposed on the edge part R2b is connected to a first wiring structure 140. As the width W12b of the edge part R2b is formed to be equal to 15% or less than 15% of the outer circumference length W1 of the first semiconductor chip 100, the second semiconductor chip 200, the third semiconductor chip 300, and the fourth semiconductor chip 400, the heat dissipation features through the bumps of the first dummy bump unit DU1 or the second dummy bump unit DU2 placed on the edge part R2b may be improved. Therefore, the risk of warpage due to heat in the edge part R2b may be reduced.

According to some example embodiments, the third region R3 may extend across the first region R1 and the second region R2. For example, the third region R3 may extend in the first direction X to intersect the first region R1 and the second region R2. The third region R3 may extend in the first direction X intersecting the second direction Y in which the bumps of a first bump line group L1 and a second bump line group L2 are placed.

According to some example embodiments, a plurality of bumps, which include first bumps 170, second bumps 270, third bumps 370, and fourth bumps 470, may be disposed throughout the first region R1, the second region R2 and the third region R3 of the first semiconductor chip 100, the second semiconductor chip 200, the third semiconductor chip 300, and the fourth semiconductor chip 400. The plurality of bumps, which include the first bumps 170, the second bumps 270, the third bumps 370, and the fourth bumps 470 arranged in the first region R1 and the second region R2, may transmit electrical signals of the first semiconductor chip 100, the second semiconductor chip 200, the third semiconductor chip 300, and the fourth semiconductor chip 400. The plurality of bumps, which include the first bumps 170, the second bumps 270, the third bumps 370, and the fourth bumps 470 disposed in the third region R3, may not transmit the electrical signals of the first semiconductor chip 100, the second semiconductor chip 200, the third semiconductor chip 300, and the fourth semiconductor chip 400. However, the present disclosure is not limited thereto. In an example embodiment, the plurality of bumps, which include the first bumps 170, the second bumps 270, the third bumps 370, and the fourth bumps 470 arranged in the third region R3, also may transmit electrical signals of the first semiconductor chip 100, the second semiconductor chip 200, the third semiconductor chip 300, and the fourth semiconductor chip 400.

According to some example embodiments, layouts in which the plurality of bumps, which include the first bumps 170, the second bumps 270, the third bumps 370 and the fourth bumps 470 are arranged, may be the same. For example, the first layout in which the plurality of first bumps 170 are arranged and the second layout in which the plurality of second bumps 270 are arranged may be the same.

According to some example embodiments, “layouts in which the plurality of bumps, which include the first bumps 170, the second bumps 270, the third bumps 370, and the fourth bumps 470, are arranged may be the same” may indicate that an arrangement of bumps connected to the wiring structures (the first wiring structure 140, a second wiring structure 240, a third wiring structure 340, and a fourth wiring structure 440) among the plurality of bumps is the same as an arrangement of bumps not connected to the wiring structures.

For example, when the first layout where the plurality of first bumps 170 are arranged and the second layout where the plurality of second bumps 270 are arranged are the same, a bump connected to the first wiring structure 140 among the plurality of first bumps 170 and a bump connected to the second wiring structure 240 among the plurality of second bumps 270 may overlap in the third direction Z. In other words, the bumps connected to the first wiring structure 140 among the plurality of first bumps 170 and the bumps connected to the second wiring structure 240 among the plurality of second bumps 270 may have the same location in the first direction X and the second direction Y.

For another example, when the first layout where the plurality of first bumps 170 are arranged and the second layout where the plurality of second bumps 270 are arranged are the same, a bump not connected to the first wiring structure 140 among the plurality of first bumps 170 and a bump not connected to the second wiring structure 240 among the plurality of second bumps 270 may overlap in the third direction Z. In other words, the bump not connected to the first wiring structure 140 among the plurality of first bumps 170 and the bump not connected to the second wiring structure 240 among the plurality of second bumps 270 may have the same location in the first direction X and the second direction Y.

According to some example embodiments, the plurality of first bumps 170 may be arranged on a bottom part of the first semiconductor chip 100 in the first layout. For example, the plurality of first bumps 170 may be arranged to overlap at least one of the first region R1, the second region R2, and the third region R3 of the first semiconductor chip 100 in the third direction Z.

According to some example embodiments, the plurality of second bumps 270 may be disposed on a bottom part of the second semiconductor chip 200 in the second layout. The plurality of second bumps 270 may be disposed between the bottom part of the second semiconductor chip 200 and the top part of the first semiconductor chip 100. For example, the plurality of second bumps 270 may be arranged to overlap at least one of the first region R1, the second region R2 and the third region R3 of the second semiconductor chip 200 in the third direction Z.

According to some example embodiments, the description of the plurality of third bumps 370 and the plurality of fourth bumps 470 is substantially the same as the description of the plurality of first bumps 170 and the plurality of second bumps 270, and is therefore omitted. Hereinafter, the explanation is based on the first semiconductor chip 100 and the plurality of first bumps 170.

According to some example embodiments, the plurality of first bumps 170 may include a first bump group G1 and a second bump group G2. The first bump group G1 and the second bump group G2 may be arranged alternately in the first direction X. For example, one first bump group G1 may be placed between the second bump groups G2 placed on both sides in the first direction X. One second bump group G2 may be placed between the first bump groups G1 placed on both sides in the first direction X.

FIG. 2 illustrates that the plurality of first bumps 170 include the two first bump groups G1 and the two second bump groups G2. However, the present disclosure is not limited thereto. For example, the plurality of first bumps 170 may include three first bump groups G1 and the two second bump groups G2. In this case, the two second bump groups G2 may be placed between the three first bump groups G1, respectively. In another example embodiment, the plurality of first bumps 170 may include two first bump groups G1 and three second bump groups G2. In this case, the two first bump groups G1 may be placed between the three second bump groups G2, respectively. In other words, the number of first bump groups G1 and the number of second bump groups G2 may not be arranged 1:1. The number of first bump groups G1 and the number of second bump groups G2 arranged may vary depending on an example embodiment.

According to some example embodiments, different types of signals may be provided to the bumps of the first bump group G1 and the bumps of the second bump group G2. For example, a power supply voltage may be provided to the bumps of the first bump group G1, and a ground voltage may be provided to the bumps of the second bump group G2. In another example embodiment, a ground voltage may be provided to the bumps of the first bump group G1, and a power voltage may be provided to the bumps of the second bump group G2.

According to some example embodiments, each of the first bump group G1 and the second bump group G2 may include some of the plurality of first bumps 170 arranged across the first region R1, the second region R2, and the third region R3.

According to some example embodiments, the first bump group G1 may include the first bump line group L1 and the first dummy bump unit DU1.

According to some example embodiments, the first bump line group L1 may overlap the first region R1. The first bump line group L1 may include a plurality of bump lines (a first adjacent bump line L1a, a first middle bump line L1b, and a second adjacent bump line L1c) overlapping the first region R1, and each of the first adjacent bump line L1a, the first middle bump line L1b, and the second adjacent bump line L1c may include a plurality of bumps. Each of the first adjacent bump line L1a, the first middle bump line L1b, and the second adjacent bump line L1c of the first bump line group L1 may be arranged in parallel along the first direction X. Each of the first adjacent bump line L1a, the first middle bump line L1b, and the second adjacent bump line L1c of the first bump line group L1 may include a plurality of bumps arranged in the second direction Y.

According to some example embodiments, the first bump line group L1 may include the first adjacent bump line L1a, the first middle bump line L1b, and the second adjacent bump line L1c. The first adjacent bump line L1a, the first middle bump line L1b, and the second adjacent bump line L1c may be placed spaced apart in the first direction X. Each of the first adjacent bump line L1a, the first middle bump line L1b, and the second adjacent bump line L1c may include a plurality of bumps disposed in the second direction Y.

According to some example embodiments, the first adjacent bump line L1a may refer to a bump line adjacent to the second bump group G2 disposed on one side of the first bump group G1 in the first direction X in the first bump line group L1. The bumps in the first adjacent bump line L1a may not be connected to the first wiring structure 140. For example, the bumps in the first adjacent bump line L1a may be physically separated from the first wiring structure 140 and electrically isolated from the first wiring structure 140.

According to some example embodiments, the second adjacent bump line L1c may refer to a bump line adjacent to the second bump group G2 disposed on the other side of the first bump group G1 in the first direction X in the first bump line group L1. The second adjacent bump line L1c may be a bump line disposed most spaced apart from the first adjacent bump line L1a in the first direction X in one first bump group G1. The bumps in the second adjacent bump line L1c may be connected to the first wiring structure 140.

According to some example embodiments, the first middle bump line L1b may be placed between the first adjacent bump line L1a and the second adjacent bump line L1c. The bumps of the first middle bump line L1b may be connected to the first wiring structure 140. FIG. 2 illustrates that the first middle bump line L1b is placed in only one row. However, the present disclosure is not limited thereto. For example, the first middle bump line L1b may be placed in two or more rows.

FIG. 2 illustrates that the first bump line group L1 contains a total of 3 bump lines. However, the present disclosure is not limited thereto. For example, the first bump line group L1 may include four or more bump lines.

According to some example embodiments, the first dummy bump unit DU1 may overlap the second region R2. The first dummy bump unit DU1 may be spaced apart from the first bump line group L1 in the second direction Y. The first dummy bump unit DU1 may include a plurality of bumps overlapping the second region R2. The bumps of the first dummy bump unit DU1 may not be connected to the first wiring structure 140. In other words, among the plurality of bumps in the first bump group G1, all bumps overlapping the second region R2 may not be connected to the first wiring structure 140. For example, among the plurality of bumps in the first bump group G1, all bumps overlapping the second region R2 may be physically separated from the first wiring structure 140 and electrically isolated from the first wiring structure 140.

According to some example embodiments, the second bump group G2 may include the second bump line group L2 and the second dummy bump unit DU2.

According to some example embodiments, the second bump line group L2 may overlap the first region R1. The second bump line group L2 may include a plurality of bumps overlapping the first region R1. The second bump line groups L2 may be placed in the first direction X with respect to each other. The second bump line group L2 may include a plurality of bumps, each disposed in the second direction Y.

According to some example embodiments, the second bump line group L2 may include a third adjacent bump line L2c, a second middle bump line L2b, and a fourth adjacent bump line L2a. The third adjacent bump line L2c, the second middle bump line L2b, and the fourth adjacent bump line L2a may be placed spaced apart in the first direction X. Each of the third adjacent bump line L2c, the second middle bump line L2b, and the fourth adjacent bump line L2a may include a plurality of bumps disposed in the second direction Y.

According to some example embodiments, the third adjacent bump line L2c may refer to the bump line adjacent to the first adjacent bump line L1a in the first direction X. The third adjacent bump line L2c may refer to a bump line adjacent to the first bump group G1 disposed on the other side of the second bump group G2 in the first direction X in the second bump line group L2. For example, the third adjacent bump line L2c may be a bump line adjacent to the first adjacent bump line L1a of the first bump group G1 disposed on the other side of the second bump group G2 in the first direction X.

According to some example embodiments, the fourth adjacent bump line L2a may refer to a bump line adjacent to the first bump group G1 disposed on one side of the second bump group G2 in the first direction X in the second bump line group L2. For example, the fourth adjacent bump line L2a may be a bump line adjacent to the second adjacent bump line L1c of the first bump group G1 disposed on one side of the second bump group G2 in the first direction X.

According to some example embodiments, the fourth adjacent bump line L2a may be a bump line disposed most spaced apart from the third adjacent bump line L2c in the first direction X in one second bump group G2. The bumps in the third adjacent bump line L2c may be connected to the first wiring structure 140. The bumps at the fourth adjacent bump line L2a may not be connected to the first wiring structure 140. For example, the bumps at the fourth adjacent bump line L2a may be physically separated from the first wiring structure 140 and electrically isolated from the first wiring structure 140.

According to some example embodiments, the second middle bump line L2b may be placed between the third adjacent bump line L2c and the fourth adjacent bump line L2a. The bumps of the second middle bump line L2b may be connected to the first wiring structure 140.

According to some example embodiments, the second dummy bump unit DU2 may overlap the second region R2 in the third direction Z. The second dummy bump unit DU2 may be separated from the second bump line group L2 in the second direction Y. The second dummy bump unit DU2 may include a plurality of bumps overlapping the second region R2 in the third direction Z. The bumps of the second dummy bump unit DU2 may be connected to the first wiring structure 140. In other words, among the plurality of bumps of the second bump group G2, all bumps overlapping the second region R2 in the third direction Z may be connected to the first wiring structure 140.

According to some example embodiments, among the bumps of the first bump group G1 and the second bump group G2, all bumps overlapping the third region R3 in the third direction Z may be connected to the first wiring structure 140. This will be described in detail below with reference to FIGS. 3 and 4.

According to some example embodiments, the second region R2 may have a higher probability of warpage occurring due to heat generated within the semiconductor package compared to the first region R1. Among the plurality of first bumps 170 arranged in the second region R2, bumps provided with the same signal may be connected to the first wiring structure 140, or none of the bumps provided with the same signal may be connected to the first wiring structure 140.

For example, the plurality of first bumps 170 may include the first bump group G1 that receives a first signal and the second bump group G2 that receives a second signal. The first signal and the second signal may include a power voltage and a ground voltage, respectively. Each of the first bump group G1 and the second bump group G2 may be placed across the first region R1 and the second region R2. All of the bumps of the first bump group G1 placed in the second region R2 may be connected to the first wiring structure 140, and all of the bumps of the second bump group G2 placed in the second region R2 may not be connected to the first wiring structure 140. For example, all of the bumps of the second bump group G2 may be physically separated from the first wiring structure 140 and electrically isolated from the first wiring structure 140. Conversely, none of the bumps of the first bump group G1 placed in the second region R2 may be connected to the first wiring structure 140, and all of the bumps of the second bump group G2 placed in the second region R2 may be connected to the first wiring structure 140.

According to some example embodiments, if all the bumps of the first bump group G1, which are placed in the second region R2 and receive the first signal, are not connected to the first wiring structure 140, even if warpage occurs due to heat in the second region R2 and some of the bumps in the first bump group G1 merge, a short may not occur. Further, if all the bumps of the second bump group G2 that receive the second signal are connected to the first wiring structure 140, thermal resistance phenomenon, such as warpage due to heat, may be reduced or disappear with the heat generated in the second region R2 being dissipated through the bumps of the first wiring structure 140 and the second bump group G2.

According to some example embodiments, unlike the second region R2, some of the plurality of first bumps 170 placed in the first region R1 and receiving the same signal may be connected to the first wiring structure 140 and some of the plurality of first bumps 170 may not be connected to the first wiring structure 140. For example, some of the bumps of the first bump group G1 disposed in the first region R1 and provided with the first signal may be connected to the first wiring structure 140, and the other remaining bumps may not be connected to the first wiring structure 140. For example, the other remaining bumps of the first bump group G1 disposed in the first region R1 may be physically separated from the first wiring structure 140 and electrically isolated from the first wiring structure 140. Likewise, some of the bumps of the second bump group G2 disposed in the first region R1 and provided with the second signal may be connected to the first wiring structure 140, and the other remaining bumps may not be connected to the first wiring structure 140. For example, the other remaining bumps of the second bump group G2 disposed in the first region R1 may be physically separated from the first wiring structure 140 and electrically isolated from the first wiring structure 140.

According to some example embodiments, the first region R1 may have a lower probability of warpage due to heat compared to the second region R2. Therefore, the possibility of merging the bumps of the first bump group G1 placed in the first region R1 or the possibility of merging the bumps of the second bump group G2 may be lower than that of the second region R2. Therefore, the thermal resistance features may be improved through heat dissipation by some of the bumps of the first bump group G1 being connected to the first wiring structure 140, and there may be improvements with respect to the short circuit between the bumps of the first bump group G1 and the adjacent bumps of the second bump group G2 by the some of the remaining bumps not being connected to the first wiring structure 140.

Referring to FIGS. 3 and 4, the semiconductor package may include the first semiconductor chip 100 to the fourth semiconductor chip 400, a package substrate 500, and a molding film 600.

According to some example embodiments, each of the first semiconductor chip 100 to the fourth semiconductor chip 400 may be a logic chip or a memory chip. The first semiconductor chip 100 to the fourth semiconductor chip 400 may all be the same type of memory chips. For example, each of the first semiconductor chip 100 to the fourth semiconductor chip 400 may be a volatile memory chip such as dynamic random access memory (DRAM) or static random access memory (SRAM). For another example, each of the first semiconductor chip 100 to the fourth semiconductor chip 400 may be a non-volatile memory chip such as phase-change RAM (PRAM), magnetoresistive RAM (MRAM), ferroelectric RAM (FeRAM), or resistive RAM (RRAM). For another example, each of the first semiconductor chip 100 to the fourth semiconductor chip 400 may be high bandwidth memory (HBM).

According to some example embodiments, additionally, some of the first semiconductor chip 100 to the fourth semiconductor chip 400 may be memory chips and the others may be logic chips. For example, some of the first semiconductor chip 100 to the fourth semiconductor chip 400 may be a microprocessor, an analog device, a digital signal processor, or an application processor.

According to some example embodiments, the first semiconductor chip 100 to the fourth semiconductor chip 400 may be stacked on the package substrate 500 in the third direction Z, for example, in the vertical direction. The first semiconductor chip 100 to the fourth semiconductor chip 400 may be electrically connected to each other through the first bump 170 to the fourth bump 470, or may be electrically connected to the package substrate 500.

According to some example embodiments, the first semiconductor chip 100 to the fourth semiconductor chip 400 and the package substrate 500 may be attached to each other by a non-conductive film (NCF). For example, a fillet layer 150 may be placed between the first semiconductor chip 100 and the package substrate 500. Here, the fillet layer 150 may include the NCF. The fillet layer 150 may be placed between the first semiconductor chip 100 and the second semiconductor chip 200. The fillet layer 150 may be placed between the second semiconductor chip 200 and the third semiconductor chip 300 and between the third semiconductor chip 300 and the fourth semiconductor chip 400.

FIG. 3 illustrates that four semiconductor chips, which include the first semiconductor chip 100 to the fourth semiconductor chip 400, are stacked, but the present disclosure is not limited thereto. For example, a semiconductor package may include semiconductor chips stacked in different numbers, such as one or two or five or more.

According to some example embodiments, the first semiconductor chip 100 may include a first semiconductor substrate 110, a first semiconductor device layer 120, first through vias 130, first front surface connection pads 142, and first rear surface connection pads 144. The first semiconductor chip 100 may be connected to the package substrate 500 through the plurality of first bumps 170.

According to some example embodiments, the first semiconductor substrate 110 may be bulk silicon or a silicon-on-insulator (SOI). In another example embodiment, the first semiconductor substrate 110 may be a silicon substrate. In another example embodiment, the first semiconductor substrate 110 may include silicon germanium, silicon germanium on insulator (SGOI), indium antimonide, lead tellurium compound, indium arsenide, indium phosphide, gallium arsenide, or gallium antimonide. However, the first semiconductor substrate 110 is not limited thereto.

According to some example embodiments, the first semiconductor substrate 110 may include a conductive region, for example, a well doped with an impurity or a structure doped with an impurity. The first semiconductor substrate 110 may have various device isolation structures, such as a shallow trench isolation (STI) structure.

According to some example embodiments, the first semiconductor device layer 120 may be placed on the bottom of the first semiconductor substrate 110. For example, the first semiconductor device layer 120 may contact the bottom of the first semiconductor substrate 110. The first semiconductor device layer 120 may include a plurality of various types of individual devices and interlayer insulating films. The individual devices may include a variety of microelectronic devices. For example, included may be metal-oxide-semiconductor field effect transistors (MOSFET), such as complementary metal-insulator-semiconductor (CMOS) transistors, system large scale integration (LSI) circuits, image sensors such as flash memory, DRAM, SRAM, EEPROM, PRAM, MRAM, RRAM, CMOS imaging sensors (CIS), micro-electro-mechanical systems (MEMS), active devices, and/or passive devices.

According to some example embodiments, the individual devices of the first semiconductor device layer 120 may be electrically connected to a conductive region formed within the first semiconductor substrate 110. The individual devices of the first semiconductor device layer 120 may be electrically separated from other neighboring individual devices by insulating films. The first semiconductor device layer 120 may include the first wiring structure 140 that electrically connects conductive regions of at least two or more individual elements and the first semiconductor substrate 110 among the plurality of individual elements.

According to some example embodiments, on the first semiconductor device layer 120, an insulation layer 115 may be formed to protect the first wiring structure 140 and other structures within the first semiconductor device layer 120 from external shock or moisture. The insulation layer 115 may contact a bottom surface of the first semiconductor device layer 120. The insulation layer 115 may expose a portion of the upper surface of the first front surface connection pads 142. For example, the insulation layer 115 may contact the first front surface connection pads 142. In example embodiments, the insulation layer 115 may be disposed between portions of the first semiconductor device layer 120 and portions of the first front surface connection pads 142.

According to some example embodiments, the first through vias 130 may penetrate the first semiconductor substrate 110. The first through vias 130 may extend from the upper surface of the first semiconductor substrate 110 toward the lower surface. For example, an upper surface of each of the first through vias 130 may be coplanar with an upper surface of the first semiconductor substrate 110, and a lower surface of each of the first through vias 130 may be coplanar with a lower surface of the first semiconductor substrate 110. The first through vias 130 may be connected to the first wiring structure 140 provided within the first semiconductor device layer 120. The first through vias 130 may only be placed in third region R3. The first through vias 130 may not be placed in the first region R1 and the second region R2. In other words, the first through vias 130 may overlap the plurality of first bumps 170 arranged in the third region R3 in the third direction Z, and may not overlap the plurality of first bumps 170 arranged in the first region R1 and the second region R2 in the third direction Z.

According to some example embodiments, each of the first through vias 130 may include a barrier film formed on the surface of the pillar shape and a buried conductive layer filling the inside of the barrier film. The barrier film may include at least one of Ti, TiN, Ta, TaN, Ru, Co, Mn, WN, Ni and NiB, but the barrier film is not limited thereto. The buried conductive layer may include at least one of Cu, Cu alloys such as CuSn, CuMg, CuNi, CuZn, CuPd, CuAu, CuRe and CuW, W, W alloy, Ni, Ru, and Co. However, the buried conductive layer is not limited thereto.

According to some example embodiments, an insulating film may be interposed between the first semiconductor substrate 110 and the first through vias 130. The insulating film may include an oxide film, a nitride film, a carbonization film, a polymer, or a combination thereof, but the insulating film is not limited thereto.

According to some example embodiments, the first wiring structure 140 may include a metal wiring layer and a via plug. For example, the first wiring structure 140 may be a multi-layer structure in which two or more metal wiring layers or two or more via plugs are alternately stacked. For example, a first metal wiring layer may be connected to a second metal wiring layer with via plugs.

According to some example embodiments, the first wiring structure 140 may include a first top wiring 140TTM. The first top wiring 140TTM may refer to the wiring layer closest to a front surface 100FS of the first semiconductor chip in the third direction Z in the multi-layer structure where the metal wiring layers and via plugs of the first wiring structure 140 are stacked alternately. FIG. 4 illustrates that the first top wiring 140TTM takes the form of a via plug, but the present disclosure is not limited thereto. For example, the first top wiring 140TTM may be a metal wiring layer disposed on a bottom part of the via plug in the third direction Z.

According to some example embodiments, the first front surface connection pads 142 may be placed on the first semiconductor device layer 120. For example, the first front surface connection pads 142 may contact the lower surface of the first semiconductor device layer 120. The first front surface connection pads 142 may be electrically connected to the first wiring structure 140 inside the first semiconductor device layer 120. For example, the first front surface connection pads 142 may contact the first top wiring 140TTM. The first front surface connection pads 142 may be electrically connected to the first through vias 130 through the first wiring structure 140. The first front surface connection pads 142 may include at least one selected from aluminum (Al), copper (Cu), nickel (Ni), tungsten (W), platinum (Pt) and gold (Au).

According to some example embodiments, the first rear surface connection pads 144 that are electrically connected to the first through vias 130 may be formed on the upper surface of the first semiconductor substrate 110. For example, each of the first rear surface connection pads 144 may contact an upper surface of a corresponding one of the first through vias 130 and a portion of the upper surface of the first semiconductor substrate 110. The first rear surface connection pads 144 may be made of the same material as the first front surface connection pads 142. Although not illustrated, an upper passivation layer may be formed to surround a portion of the side surface of the first through vias 130 on the top surface of the first semiconductor substrate 110.

According to some example embodiments, the plurality of first bumps 170 may be placed on the bottom part of the first semiconductor chip 100. The plurality of first bumps 170 may be placed on the front surface 100FS of the first semiconductor chip. Each of the plurality of first bumps 170 may be disposed in contact with a corresponding one of the first front surface connection pads 142. The plurality of first bumps 170 may electrically connect the first semiconductor chip 100 to the package substrate 500. The plurality of first bumps 170 may receive at least one of a control signal, a power signal, and a ground signal for operation of the first semiconductor chip 100 to the fourth semiconductor chip 400 from the outside. The plurality of first bumps 170 may receive data signals to be stored in the first semiconductor chip 100 to the fourth semiconductor chip 400 from an external source. The plurality of first bumps 170 may externally provide data stored in the first semiconductor chip 100 to the fourth semiconductor chip 400. For example, each of the plurality of first bumps 170 may be a pillar structure, a ball structure, or a solder layer.

Referring to FIGS. 2 to 4, first bumps 170_R3G1 of the first bump group G1 and bumps 170_R3G2 of the second bump group G2 placed in the third region R3 may be connected to the first wiring structure 140. Specifically, the first bumps 170_R3G1 of the first bump group G1 and the bumps 170_R3G2 of the second bump group G2 arranged in the third region R3 may be connected to the first wiring structure 140 through the first front surface connection pads 142.

According to some example embodiments, the first front surface connection pads 142 disposed on the first bumps 170_R3G1 of the first bump group G1 disposed in the third region R3 and the bumps 170_R3G2 of the second bump group G2 disposed in the third region R3 may be in contact with the first wiring structure 140. The first front surface connection pads 142 disposed on the first bumps 170_R3G1 of the first bump group G1 and the bumps 170_R3G2 of the second bump group G2 disposed in the third region R3 may penetrate the insulation layer 115.

According to some example embodiments, the first top wiring 140TTM, which overlaps the first bumps 170_R3G1 of the first bump group G1 placed in the third region R3 and the bumps 170_R3G2 of the second bump group G2 placed in the third region R3 in the third direction Z, may be exposed through the insulation layer 115. The first top wiring 140TTM, which overlaps the first bumps 170_R3G1 of the first bump group G1 placed in the third region R3 and the bumps 170_R3G2 of the second bump group G2 placed in the third region R3 in the third direction Z, may directly contact the first front surface connection pads 142.

According to some example embodiments, each of the first front surface connection pads 142, which are placed on the first bumps 170_R3G1 of the first bump group G1 placed in the third region R3 and on the bumps 170_R3G2 of the second bump group G2 placed in the third region R3, may include a penetration part 142a that penetrates the insulation layer 115, and a connection part 142b that connects the penetration part 142a and the first bump 170_R3G1 of the first bump group G1 and the bump 170_R3G2 of the second bump group G2 placed in the third region R3, respectively. In the first direction X and the second direction Y, the width of the penetration part 142a may be smaller than the width of the connection part 142b.

Referring to FIGS. 2, 5 and 6, bumps 170_DU1 of the first dummy bump unit DU1 placed in the second region R2 may not be connected to the first wiring structure 140. For example, the bumps 170_DU1 of the first dummy bump unit DU1 placed in the second region R2 may be physically separated from the first wiring structure 140 and electrically isolated from the first wiring structure 140. Bumps 170_DU2 of the second dummy bump unit DU2 disposed in the second region R2 may be connected to the first wiring structure 140.

According to some example embodiments, the first front surface connection pads 142 disposed on the bumps 170_DU1 of the first dummy bump unit DU1 may not contact the first wiring structure 140. The first front surface connection pads 142 disposed on the bumps 170_DU1 of the first dummy bump unit DU1 may be spaced apart from the first wiring structure 140 with the insulation layer 115 therebetween. A front surface 140FS of the first wiring structure that overlaps the bumps 170_DU1 of the first dummy bump unit DU1 in the third direction Z may be covered by the insulation layer 115. For example, the insulation layer 115 may contact the front surface 140FS of each first top wiring 140TTM that overlaps the bumps 170_DU1 of the first dummy bump unit DU1 in the third direction Z.

According to some example embodiments, the first top wirings 140TTM, which overlap the bumps 170_DU1 of the first dummy bump unit DU1 in the third direction Z, may be separated from the first front surface connection pads 142 with the insulation layer 115 in between. For example, the insulation layer 115 may be disposed between the first top wirings 140TTM, which overlap the bumps 170_DU1 of the first dummy bump unit DU1 in the third direction Z, and corresponding ones of the first front surface connection pads 142, and may electrically separate the first wiring structure 140 from the bumps 170_DU1 of the first dummy bump unit DU1. The first top wiring 140TTM overlapping the bumps 170_DU1 of the first dummy bump unit DU1 in the third direction Z may be covered by the insulation layer 115.

According to some example embodiments, the first front surface connection pads 142 disposed on the bumps 170_DU2 of the second dummy bump unit DU2 may be in contact with the first wiring structure 140. The first front surface connection pads 142 disposed on the bumps 170_DU2 of the second dummy bump unit DU2 may penetrate the insulation layer 115.

According to some example embodiments, the first top wirings 140TTM, which overlap the bump 170_DU2 of the second dummy bump unit DU2 in the third direction Z, may be exposed through the insulation layer 115. The first top wirings 140TTM, which overlap the bump 170_DU2 of the second dummy bump unit DU2 in the third direction Z, may directly contact a corresponding one of the first front surface connection pads 142.

According to some example embodiments, each of the first front surface connection pads 142 placed on the bumps 170_DU2 of the second dummy bump unit DU2 may include the penetration part 142a that penetrates the insulation layer 115 and the connection part 142b that connects the penetration part 142a and the bump 170_DU2 of the second dummy bump unit DU2. In the first direction X and the second direction Y, the width of the penetration part 142a may be smaller than the width of the connection part 142b.

Referring to FIGS. 2, 7 and 8, a bump 170_L1a disposed on the first adjacent bump line L1a and a bump 170_L1b disposed on the first middle bump line L1b may include some bumps of the first bump group G1 disposed in the first region R1. A bump 170_L2c disposed on the third adjacent bump line L2c and a bump 170_L2b disposed on the second middle bump line L2b may include some bumps of the second bump group G2 disposed on the first region R1.

According to some example embodiments, the bumps 170_L1a placed at the first adjacent bump line L1a may not be connected to the first wiring structure 140. For example, the bumps 170_L1a of the first adjacent bump line L1a may be physically separated from the first wiring structure 140 and electrically isolated from the first wiring structure 140. The bumps 170_L1b placed on the first middle bump line L1b, the bumps 170_L2c placed on the third adjacent bump line L2c, and the bumps 170_L2b placed on the second middle bump line L2b may be connected to the first wiring structure 140.

As the semiconductor package is miniaturized, there is a possibility that the bumps 170_L1a placed on the first adjacent bump line L1a and the bumps 170_L2c placed on the third adjacent bump line L2c may be merged during the manufacturing process. Meanwhile, if the bumps 170_L1a placed on the first adjacent bump line L1a are not connected to the first wiring structure 140, even if the bumps 170_L1a placed on the first adjacent bump line L1a and the bumps 170_L2c placed on the third adjacent bump line L2c are merged, an electrical short circuit may not occur. Therefore, as the bumps 170_L1a placed on the first adjacent bump line L1a are not connected to the first wiring structure 140, the risk of an electrical short circuit between the bumps 170_L1a placed on the first adjacent bump line L1a and the bumps 170_L2c placed on the third adjacent bump line L2c may be reduced.

According to some example embodiments, the first front surface connection pads 142 disposed on the bumps 170_L1a disposed at the first adjacent bump line L1a may not contact the first wiring structure 140. The first front surface connection pads 142 disposed on the bumps 170_L1a disposed at the first adjacent bump line L1a may be spaced apart from the first wiring structure 140 with the insulation layer 115 interposed therebetween. The front surfaces 140FS of the first wiring structure that overlap the bumps 170_L1a placed on the first adjacent bump line L1a in the third direction Z may be covered by the insulation layer 115.

According to some example embodiments, the first top wiring 140TTM that overlaps the bumps 170_L1a placed on the first adjacent bump line L1a in the third direction Z may be separated from the first front surface connection pads 142 with the insulation layer 115 in between. The first top wiring 140TTM overlapping the bumps 170_L1a placed on the first adjacent bump line L1a in the third direction Z may be covered by the insulation layer 115.

According to some example embodiments, the first front surface connection pads 142 disposed on the bumps 170_L1b placed at the first middle bump line L1b, the bumps 170_L2c placed at the third adjacent bump line L2c, and the bumps 170_L2b placed at the second middle bump line L2b, respectively, may be in contact with the first wiring structure 140. The first front surface connection pads 142 disposed on the bumps 170_L1b placed at the first middle bump line L1b, the bumps 170_L2c placed at the third adjacent bump line L2c, and the bumps 170_L2b placed at the second middle bump line L2b, respectively, may penetrate the insulation layer 115.

According to some example embodiments, the first top wiring 140TTM, which overlaps the bumps 170_L1b placed at the first middle bump line L1b, the bumps 170_L2c placed at the third adjacent bump line L2c, and the bumps 170_L2b placed at the second middle bump line L2b in the third direction Z, may be exposed through the insulation layer 115. The first top wiring 140TTM, which overlaps the bumps 170_L1b placed at the first middle bump line L1b, the bumps 170_L2c placed at the third adjacent bump line L2c, and the bumps 170_L2b placed at the second middle bump line L2b in the third direction Z respectively, may directly contact the first front surface connection pads 142.

According to some example embodiments, each of the first front surface connection pads 142, which are placed on the bumps 170_L1b placed at the first middle bump line L1b, the bumps 170_L2c placed at the third adjacent bump line L2c and the bumps 170_L2b placed at the second middle bump line L2b, respectively, may include the penetration part 142a that penetrates the insulation layer 115 and the connection part 142b that connects the penetration part 142a to the bumps 170_L1b placed at the first middle bump line L1b, the bumps 170_L2c placed at the third adjacent bump line L2c and the bumps 170_L2b placed at the second middle bump line L2b, respectively.

Referring to FIGS. 2, 9 and 10, the bumps 170_DU2 of the second dummy bump unit DU2 may be connected to the first wiring structure 140. The bumps 170_R3G2 of the second bump group G2 disposed in the third region R3 may be connected to the first wiring structure 140.

According to some example embodiments, the first front surface connection pads 142 disposed on the bumps 170_DU2 of the second dummy bump unit DU2 may be in contact with the first wiring structure 140. The first front surface connection pads 142 disposed on the bumps 170_DU2 of the second dummy bump unit DU2 may penetrate the insulation layer 115.

According to some example embodiments, the first top wiring 140TTM, which overlaps the bumps 170_DU2 of the second dummy bump unit DU2 in the third direction Z, may be exposed through the insulation layer 115. The first top wiring 140TTM, which overlaps the bumps 170_DU2 of the second dummy bump unit DU2 in the third direction Z, may directly contact the first front surface connection pads 142.

By the bumps 170_DU2 of the second dummy bump unit DU2 being connected to the first wiring structure 140, heat inside the semiconductor package may be dissipated through the first wiring structure 140 and the bumps 170_DU2 of the second dummy bump unit DU2. Heat may be generated when the first wiring structure 140 transmits electrical signals between the package substrate 500 and the first semiconductor chip 100. Meanwhile, by the bumps 170_DU2 of the second dummy bump unit DU2 that are not electrically connected to the first through vias 130 being connected to the first wiring structure 140, the heat generated in the first wiring structure 140 may be dissipated through the bumps 170_DU2 of the second dummy bump unit DU2.

According to some example embodiments, the first front surface connection pads 142 placed on the bumps 170_R3G2 of the second bump group G2 placed in third region R3 may be in contact with the first wiring structure 140. The first front surface connection pads 142 disposed on the bumps 170_R3G2 of the second bump group G2 disposed in the third region R3 may penetrate the insulation layer 115.

According to some example embodiments, the first front surface connection pads 142 placed on the bumps 170_R3G2 of the second bump group G2 placed in third region R3 may be in contact with the first wiring structure 140. The first front surface connection pads 142 placed on the bumps 170_R3G2 of the second bump group G2 placed in third region R3 may penetrate the insulation layer 115.

According to some example embodiments, the first top wiring 140TTM overlapping the bumps 170_R3G2 of the second bump group G2 placed in the third region R3 in the third direction Z may be exposed through the insulation layer 115. The first top wiring 140TTM overlapping the bumps 170_R3G2 of the second bump group G2 placed in the third region R3 in the third direction Z may directly contact the first front surface connection pads 142.

According to some example embodiments, each of the first front surface connection pads 142, which are placed on the bumps 170_DU2 of the second dummy bump unit DU2 placed in the second region R2 and the bumps 170_R3G2 of the second bump group G2 placed in the third region R3, respectively, may include the penetration part 142a that penetrates the insulation layer 115 and the connection part 142b that connects the penetration part 142a to the bumps 170_DU2 of the second dummy bump unit DU2 and the bumps 170_R3G2 of the second bump group G2, respectively.

Referring to FIGS. 2, 11 and 12, the bumps 170_DU1 of the first dummy bump unit DU1 disposed in the first region R1 may not be connected to the first wiring structure 140. For example, the bumps 170_DU1 of the first dummy bump unit DU1 disposed in the first region R1 may be physically separated from the first wiring structure 140 and electrically isolated from the first wiring structure 140. The first bumps 170_R3G1 of the first bump group G1 disposed in the third region R3 may be connected to the first wiring structure 140.

According to some example embodiments, the first front surface connection pads 142 disposed on the bumps 170_DU1 of the first dummy bump unit DU1 disposed in the first region R1 may not contact the first wiring structure 140. The first front surface connection pads 142 placed on the bumps 170_DU1 of the first dummy bump unit DU1 placed in the first region R1 may be spaced apart from the first wiring structure 140 with the insulation layer 115 in between. The front surfaces 140FS of the first wiring structure that overlap the bumps 170_DU1 of the first dummy bump unit DU1 disposed in the first region R1 in the third direction Z may be covered by the insulation layer 115.

According to some example embodiments, the first top wiring 140TTM, which overlaps the bumps 170_DU1 of the first dummy bump unit DU1 disposed in the first region R1 in the third direction Z, may be spaced apart from the first front surface connection pads 142 with the insulation layer 115 in between. The first top wiring 140TTM overlapping the bumps 170_DU1 of the first dummy bump unit DU1 placed in the first region R1 in the third direction Z may be covered by the insulation layer 115.

According to some example embodiments, the first front surface connection pads 142 placed on the first bumps 170_R3G1 of the first bump group G1 placed in third region R3 may be in contact with the first wiring structure 140. The first front surface connection pads 142 placed on the first bumps 170_R3G1 of the first bump group G1 placed in third region R3 may penetrate the insulation layer 115.

According to some example embodiments, the first top wiring 140TTM overlapping the first bumps 170_R3G1 of the first bump group G1 placed in the third region R3 in the third direction Z may be exposed through the insulation layer 115. The first top wiring 140TTM overlapping the first bumps 170_R3G1 of the first bump group G1 placed in the third region R3 in the third direction Z may be in direct contact with the first front surface connection pads 142.

According to some example embodiments, each of the first front surface connection pads 142 placed on the first bumps 170_R3G1 of the first bump group G1 placed in the third region R3 may include the penetration part 142a that penetrates the insulation layer 115 and the connection part 142b connecting the penetration part 142a and each first bump 170_R3G1 of the first bump group G1 placed in the third region R3.

According to some example embodiments, the second semiconductor chip 200 may include a second semiconductor substrate 210, a second semiconductor device layer 220 having the second wiring structure 240, second through vias 230, second front surface connection pads 242, second rear surface connection pads 244, and the second bumps 270.

According to some example embodiments, the second semiconductor chip 200 may be placed on the first semiconductor chip 100. The second semiconductor chip 200 may be electrically connected to the first semiconductor chip 100 through the second bumps 270 placed between the first semiconductor chip 100 and the second semiconductor chip 200.

According to some example embodiments, the fillet layer 150 may be disposed between the upper surface of the first semiconductor chip 100 and the bottom surface of the second semiconductor chip 200. The fillet layer 150 may attach the second semiconductor chip 200 onto the first semiconductor chip 100. The fillet layer 150 may surround the first rear surface connection pads 144, the second bumps 270, and the second front surface connection pads 242 that are placed between the first semiconductor chip 100 and the second semiconductor chip 200.

According to some example embodiments, the fillet layer 150 may be formed to protrude outward from the side surfaces of the first semiconductor chip 100 and the second semiconductor chip 200. The fillet layer 150 formed to protrude outward from the side surfaces of the first semiconductor chip 100 and the second semiconductor chip 200 may cover a portion of the side surfaces of the first semiconductor chip 100 and the second semiconductor chip 200. The side surface of the fillet layer 150 that protrudes outward from the side of the first semiconductor chip 100 and the second semiconductor chip 200 may form a curved surface.

According to some example embodiments, the third semiconductor chip 300 may be placed on the second semiconductor chip 200. The third semiconductor chip 300 may include a third semiconductor substrate 310, a third semiconductor device layer 320 having the third wiring structure 340, third through vias 330, third front surface connection pads 342, third rear surface connection pads 344, and the third bumps 370.

According to some example embodiments, the fourth semiconductor chip 400 may be placed on the third semiconductor chip 300. The fourth semiconductor chip 400 may include a fourth semiconductor substrate 410, a fourth semiconductor device layer 420 having the fourth wiring structure 440, fourth front surface connection pads 442, and the fourth bumps 470. Unlike the first semiconductor chip 100 to the third semiconductor chip 300, the fourth semiconductor chip 400 may not include a through via and a rear surface connection pad.

According to some example embodiments, the fillet layer 150 may be disposed between the upper surface of the second semiconductor chip 200 and the bottom surface of the third semiconductor chip 300. The fillet layer 150 may surround the second rear surface connection pads 244, the third bumps 370, and the third front surface connection pads 342 placed between the second semiconductor chip 200 and the third semiconductor chip 300.

According to some example embodiments, the fillet layer 150 may be placed between the upper surface of the third semiconductor chip 300 and the bottom surface of the fourth semiconductor chip 400. The fillet layer 150 may surround the third rear surface connection pads 344, the fourth bumps 470, and the fourth front surface connection pads 442 placed between the third semiconductor chip 300 and the fourth semiconductor chip 400.

According to some example embodiments, the second semiconductor chip 200 to the fourth semiconductor chip 400 may be substantially the same as or similar to the first semiconductor chip 100. Therefore, detailed descriptions of the second semiconductor chip 200 to the fourth semiconductor chip 400 will be omitted.

According to some example embodiments, the package substrate 500 may be, for example, a printed circuit board (PCB), a ceramic substrate, or an interposer. Alternatively, the package substrate 500 may be a semiconductor chip including semiconductor devices. The package substrate 500 may function as a support substrate for the semiconductor package. For example, the above-described first semiconductor chip 100 to the fourth semiconductor chip 400 may be stacked on the package substrate 500.

According to some example embodiments, the package substrate 500 may include a substrate body part 510, bottom surface pads 542, and upper surface pads 544. The bottom surface pads 542 may be disposed on the bottom surface of the substrate body part 510. The upper surface pads 544 may be disposed on the upper surface of the substrate body part 510. Each of the upper surface pads 544 may contact a respective one of the plurality of first bumps 170. External connection terminals 570 may be disposed at the bottom part of the package substrate 500. The external connection terminals 570 may be disposed on the bottom surface pads 542. For example, each of the external connection terminals 570 may be a solder ball or a bump.

According to some example embodiments, the fillet layer 150 may be formed between the package substrate 500 and the first semiconductor chip 100. The fillet layer 150 may surround the first bumps 170 and the first front surface connection pads 142 between the package substrate 500 and the first semiconductor chip 100.

According to some example embodiments, the fillet layer 150 may be formed to protrude outward from the side surface of the first semiconductor chip 100. The fillet layer 150 formed by protruding to the outside of the side surface of the first semiconductor chip 100 may cover a portion of the side surface of the first semiconductor chip 100. The side surface of the fillet layer 150, which protrudes outward from the side surface of the first semiconductor chip 100, may form a curved surface.

According to some example embodiments, the molding film 600 may be formed on the package substrate 500. The molding film 600 may cover the fillet layer 150 and the first semiconductor chip 100 to the fourth semiconductor chip 400. The molding film 600 may include a polymer such as, for example, resin. For example, the molding film 600 may include an epoxy molding compound (EMC). However, the molding film 600 is not limited thereto.

According to some example embodiments, the molding film 600 may not be placed between the package substrate 500 and the first semiconductor chip 100. Specifically, since the fillet layer 150 fills the space between the package substrate 500 and the first semiconductor chip 100, the molding film 600 may not be placed between the package substrate 500 and the first semiconductor chip 100.

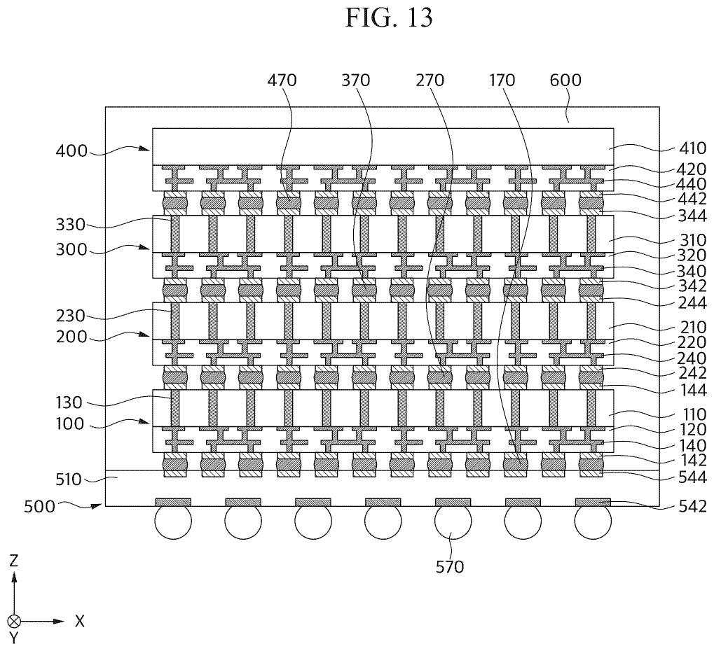

FIG. 13 is a cross-sectional view to explain a semiconductor package according to another example embodiment. For convenience of explanation, differences from those described with reference to FIG. 3 will be mainly explained.

Referring to FIG. 13, in the semiconductor package, the molding film 600 may fill the space between the package substrate 500 and the first semiconductor chip 100 to the fourth semiconductor chip 400. The fillet layer 150 of FIG. 3 formed to protrude to the outside of the side surface of the first semiconductor chip 100 to the fourth semiconductor chip 400 may not be disposed.

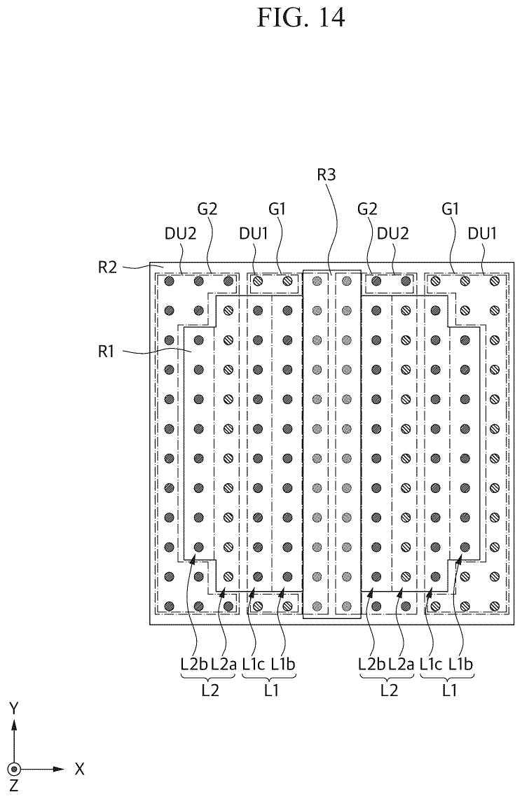

FIG. 14 is a layout diagram of a semiconductor package according to another example embodiment. For convenience of explanation, differences from those described with reference to FIG. 2 will be mainly explained.

Referring to FIG. 14, the third region R3 may extend across the first region R1 and the second region R2. For example, the third region R3 may extend in the second direction Y to intersect the first region R1 and the second region R2. The third region R3 may extend in the same direction as the second direction Y in which the bumps of the first bump line group L1 and the second bump line group L2 are disposed.

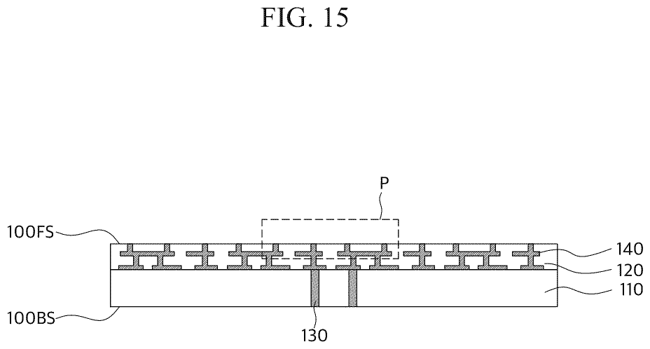

FIGS. 15 to 21 are diagrams of intermediate process for explaining a method of manufacturing a semiconductor package according to some example embodiments. For reference, FIGS. 15 to 21 illustrate intermediate process in the method of manufacturing the semiconductor package with the cross section shown in FIG. 11.

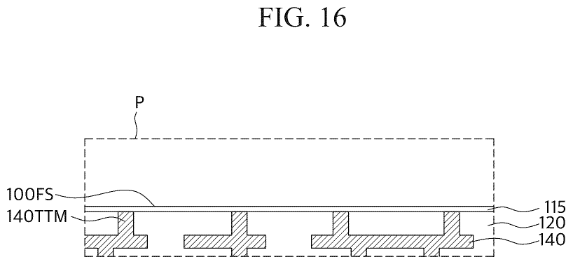

Referring to FIGS. 15 and 16, the first semiconductor substrate 110, the first through vias 130, the first semiconductor device layer 120, and the first wiring structure 140 may be formed.

Specifically, after the first semiconductor substrate 110 is formed, the first through vias 130 may be formed to pass through the first semiconductor substrate 110. Subsequently, the first semiconductor device layer 120 including the first wiring structure 140 may be formed on the first semiconductor substrate 110.

According to some example embodiments, the insulation layer 115 may be formed on the first semiconductor device layer 120. The insulation layer 115 may be formed to extend along the first semiconductor device layer 120. The insulation layer 115 may be formed on the first semiconductor device layer 120 to cover the first top wiring 140TTM. One surface of the insulation layer 115 disposed on the opposite side from the surface in contact with the first semiconductor device layer 120 of the insulation layer 115 may be the front surface 100FS of the first semiconductor chip.

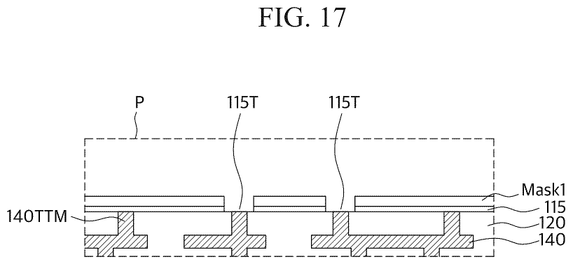

Further, referring to FIG. 17, a trench 115T may be formed within the insulation layer 115. Specifically, the trench 115T may be formed by removing a portion of the insulation layer 115 that is exposed and not covered by a first mask Mask1, using the first mask Mask1. A portion of the first top wiring 40TTM may be exposed through the trench 115T.

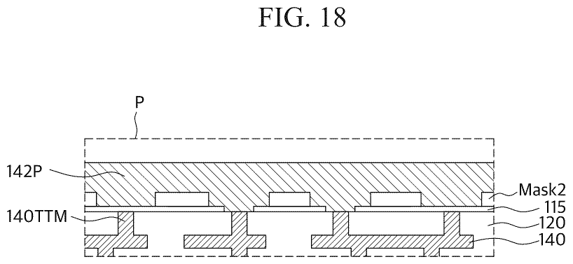

Further, referring to FIG. 18, a pre first front surface connection pad 142P may be formed using a second mask Mask2.

Specifically, after the first mask Mask1 in FIG. 17 is removed, the second mask Mask2 may be formed on the insulation layer 115. The pre first front surface connection pad 142P may fill the portion where the insulation layer 115 is exposed between the trench 115T in FIG. 17 that is exposed and not covered by the second mask Mask2 and the second mask Mask2.

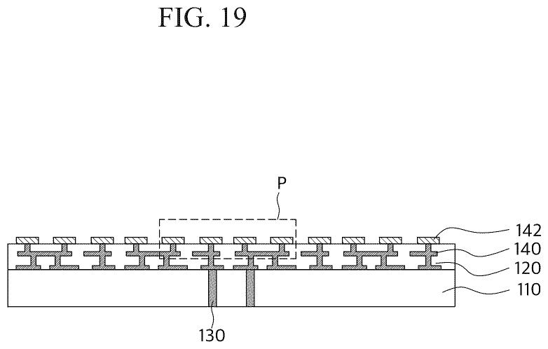

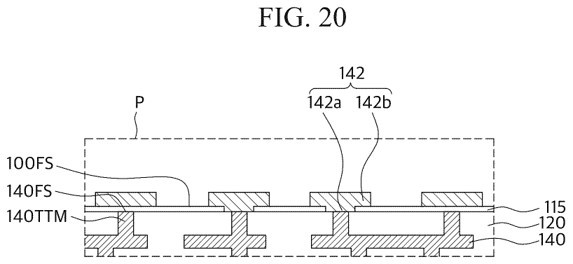

Further, referring to FIGS. 19 and 20, the first front surface connection pad 142 may be formed.

Specifically, a portion of the pre first front surface connection pad 142P in FIG. 18 covering the second mask Mask2 in FIG. 18 may be removed, and the second mask Mask2 in FIG. 18 may be removed. For example, the pre first front surface connection pad 142P in FIG. 18 formed above the upper surface of the second mask Mask2 in FIG. 18 may be removed by a grinding process such as a Chemical Mechanical Polishing (CMP) process. The pre first front surface connection pad 142P in FIG. 18 formed above the upper surface of the second mask Mask2 in FIG. 18 may be removed to form the first front surface connection pads 142 and the second mask Mask2 in FIG. 18 to be exposed. Further, the exposed second mask Mask2 in FIG. 18 may be removed.

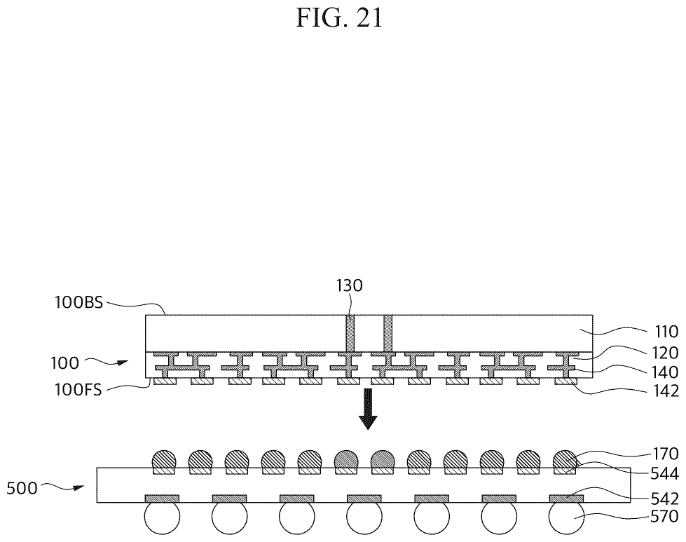

Further, referring to FIG. 21, the first semiconductor chip 100 may be connected to the package substrate 500 so that the plurality of first bumps 170 on the package substrate 500 and the first front surface connection pads 142 formed on the front surface 100FS of the first semiconductor chip are aligned.

Further, referring to FIG. 3, just as the first semiconductor chip 100 is stacked on the package substrate 500, the second semiconductor chip 200 to the fourth semiconductor chip 400 may be connected to the first semiconductor chip 100.

In the above, various embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiment may be implemented with some elements deleted, and each example embodiment may be implemented in combination with each other.

1. A semiconductor package comprising:
a package substrate;
a first semiconductor chip comprising a first region disposed on the package substrate and a second region disposed on the package substrate and arranged to surround the first region; and
a plurality of first layer bumps arranged in a first layout on a bottom part of the first semiconductor chip,
wherein the first semiconductor chip comprises a first wiring structure disposed on the plurality of first layer bumps,
wherein the plurality of first layer bumps comprise a first bump group and a second bump group arranged alternately in a first direction,
wherein the first bump group comprises:
a first bump line group formed by a plurality of first bump lines arranged in the first direction, the plurality of first bump lines overlapping the first region and comprising a plurality of first bumps arranged in rows along a second direction intersecting the first direction; and
a first dummy bump unit comprising a plurality of first dummy bumps overlapping the second region,
wherein the second bump group comprises:
a second bump line group formed by a plurality of second bump lines arranged in the first direction, the plurality of second bump lines overlapping the first region and comprising a plurality of second bumps arranged in rows along the second direction; and
a second dummy bump unit comprising a plurality of second dummy bumps overlapping the second region,
wherein the plurality of first dummy bumps of the first dummy bump unit are not connected to the first wiring structure, and
wherein the plurality of second dummy bumps of the second dummy bump unit are connected to the first wiring structure.

2. The semiconductor package of claim 1,
wherein the second region comprises:
an extension part extending in the first direction or the second direction; and
edge parts disposed on both sides of the extension part, in a direction in which the extension part extends, and
wherein the edge parts have a width that is greater than a width of the extension part in a direction that intersects the direction in which the extension part extends.

3. The semiconductor package of claim 2, wherein the width of the extension part is greater than the width of the edge parts in the direction in which the extension part extends.

4. The semiconductor package of claim 2, wherein the width of each of the edge parts on the both sides of the extension part in the direction in which the extension part extends is equal to 15% or less than 15% of a length of the second region.

5. The semiconductor package of claim 1,
wherein the first semiconductor chip further comprises a third region disposed on the package substrate and disposed across the first region and the second region in any one of the first direction and the second direction, and
wherein bumps of the plurality of first bumps of the first bump group and bumps of the plurality of second bumps of the second bump group overlapping the third region are connected with the first wiring structure.

6. The semiconductor package of claim 5,
wherein the first semiconductor chip further comprises:
a semiconductor substrate disposed on the first wiring structure; and
a first through via that penetrates the semiconductor substrate and is connected to the first wiring structure, and
wherein the first through via is disposed in the third region.

7. The semiconductor package of claim 1,
wherein the first bump line group comprises:
a first adjacent bump line disposed on one side of the first bump group in the first direction and adjacent to the second bump group; and
a second adjacent bump line disposed on another side of the first bump group in the first direction, and
wherein the first adjacent bump line includes bumps that are not connected to the first wiring structure.

8. The semiconductor package of claim 7, wherein the second adjacent bump line includes bumps that are connected with the first wiring structure.

9. The semiconductor package of claim 7,
wherein the second bump line group comprises a third adjacent bump line disposed on another side of the second bump group in the first direction and adjacent to the first adjacent bump line, and
wherein the third adjacent bump line includes bumps that are connected with the first wiring structure.

10. The semiconductor package of claim 7,
wherein the second bump line group comprises a fourth adjacent bump line disposed on one side of the second bump group in the first direction, and
wherein the fourth adjacent bump line includes bumps that are not connected to the first wiring structure.

11. The semiconductor package of claim 1, wherein a type of a first signal provided to the plurality of first layer bumps of the first bump group is different from a type of a second signal provided to the plurality of first layer bumps of the second bump group.

12. The semiconductor package of claim 1, further comprising:
a second semiconductor chip disposed on the first semiconductor chip; and
a plurality of second layer bumps arranged in a second layout on a bottom part of the second semiconductor chip,
wherein the first layout and the second layout are identical.

13. The semiconductor package of claim 1,
wherein the first semiconductor chip further comprises first front surface connection pads disposed on a bottom part of the first wiring structure and disposed on the plurality of first layer bumps,
wherein connection pads of the first front surface connection pads disposed on the plurality of first dummy bumps of the first dummy bump unit are spaced apart from the first wiring structure, and
wherein connection pads of the first front surface connection pads disposed on the plurality of second dummy bumps of the second dummy bump unit are in contact with the first wiring structure.

14. The semiconductor package of claim 13,
wherein the first semiconductor chip further comprises an insulation layer disposed on the bottom part of the first wiring structure,
wherein the connection pads of the first front surface connection pads disposed on the plurality of first dummy bumps of the first dummy bump unit are spaced apart from the first wiring structure with the insulation layer in between, and
wherein the connection pads of the first front surface connection pads disposed on the plurality of second dummy bumps of the second dummy bump unit penetrate the insulation layer.

15. The semiconductor package of claim 14,
wherein each of the connection pads of the first front surface connection pads disposed on the plurality of second dummy bumps of the second dummy bump unit comprises:
a penetration part that penetrates the insulation layer; and
a connection part disposed between the penetration part and a corresponding one of the plurality of second dummy bumps of the second dummy bump unit, and
wherein the penetration part has a width that is smaller than a width of the connection part.

16. A semiconductor package comprising:
a package substrate;
a first semiconductor chip disposed on the package substrate and comprising a first region and a second region surrounding the first region; and
a plurality of first layer bumps disposed on a bottom part of the first semiconductor chip in a first layout,
wherein the first semiconductor chip comprises a first wiring structure disposed on the plurality of first layer bumps,
wherein the plurality of first layer bumps disposed in the first layout comprise a first bump group and a second bump group that are arranged alternately in a first direction,
wherein the first bump group comprises a first bump line group formed by a plurality of first bump lines arranged in the first direction, the plurality of first bump lines overlapping the first region and comprising a plurality of first bumps arranged in rows along a second direction intersecting the first direction,
wherein the second bump group comprises a second bump line group formed by a plurality of second bump lines arranged in the first direction, the plurality of second bump lines overlapping the first region and comprising a plurality of second bumps arranged in rows along the second direction,
wherein the first bump line group comprises:
a first adjacent bump line adjacent to the second bump group disposed on one side of the first bump group in the first direction; and
a second adjacent bump line disposed on another side of the first bump group in the first direction,
wherein the second bump line group comprises:
a third adjacent bump line that is disposed on one side of the second bump group in the first direction and is adjacent to the first adjacent bump line; and
a fourth adjacent bump line that is disposed on another side of the second bump group in the first direction, and
wherein bumps of the first adjacent bump line and bumps of the fourth adjacent bump line are not connected to the first wiring structure.

17. The semiconductor package of claim 16,
wherein the first region comprises:
a center part;
a first protruding part formed to protrude from the center part in the first direction; and
a second protruding part formed to protrude from the center part in the second direction, and
wherein a first distance between an outer circumference of the second region and the first protruding part in the first direction is shorter than a second distance between an outer circumference of the second region and the first protruding part in the second direction.

18. The semiconductor package of claim 17, wherein the second distance is equal to 15% or less than 15% of the outer circumference of the second region extending in the second direction.

19. The semiconductor package of claim 16,
wherein the first semiconductor chip further comprises:
a third region extending across the first region and the second region in any one of the first direction and the second direction,
a first semiconductor substrate disposed on the first wiring structure; and
a first through via that penetrates the first semiconductor substrate and is connected to the first wiring structure, and
wherein bumps of the first bump group overlapping the third region and bumps of the second bump group are connected with the first wiring structure.

20. A semiconductor package comprising:
a package substrate;
a first semiconductor chip that comprises a first region disposed on the package substrate, a second region disposed on the package substrate and arranged to surround the first region, and a third region disposed on the package substrate and disposed across the first region and the second region; and
a plurality of first layer bumps disposed on a bottom part of the first semiconductor chip,
wherein the first semiconductor chip comprises:
a first wiring structure disposed on the plurality of first layer bumps;
first front surface connection pads disposed between the first wiring structure and the plurality of first layer bumps;
a first semiconductor substrate disposed on the first wiring structure; and
a first through via that penetrates the first semiconductor substrate and is connected to the first wiring structure,
wherein the plurality of first layer bumps comprise a first bump group and a second bump group that are arranged alternately in a first direction,
wherein the first bump group comprises:
a first bump line group formed by a plurality of first bump lines arranged in the first direction, the plurality of first bump lines overlapping the first region and comprising a plurality of first bumps arranged in rows along a second direction intersecting the first direction; and
a first dummy bump unit comprising a plurality of first dummy bumps overlapping the second region,
wherein the second bump group comprises:
a second bump line group formed by a plurality of second bump lines arranged in the first direction, the plurality of second bump lines overlapping the first region and comprising a plurality of second bumps arranged in rows along the second direction; and
a second dummy bump unit comprising a plurality of second dummy bumps overlapping the second region,
wherein the first bump line group comprises:
a first adjacent bump line that is disposed on one side of the first bump group in the first direction and is adjacent to the second bump group; and
a second adjacent bump line disposed on another side of the first bump group in the first direction,
wherein the first wiring structure comprises a first top wiring disposed closest to the first front surface connection pads in a third direction intersecting the first direction and the second direction,
wherein the first adjacent bump line includes bumps that are not connected with the first top wiring,
wherein the second adjacent bump line includes bumps that are connected with the first top wiring,
wherein the first dummy bump unit includes bumps that are not connected with the first top wiring,
wherein the second dummy bump unit includes bumps that are connected with the first top wiring, and
wherein the first through via overlaps the third region in the third direction and does not overlap the first region and the second region in the third direction.

21-24. (canceled)
